(19) United States
(12) Patent Application Publication
(10) Pub. No.: US 2016/0280947 A1
(43) Pub. Date: Sep. 29, 2016

(54) TRANSPARENT CONDUCTIVE INK COMPOSITED BY CARBON NANO TUBES AND POLYMERS, AND METHOD FOR PREPARING SAME

(71) Applicants: BEIJING AGLAIA TECHNOLOGY DEVELOPMENT CO., LTD., Beijing (CN); GUANGDONG AGLAIA OPTOELECTRONIC MATERIALS CO., LTD., Foshan, Guangdong (CN)

(72) Inventors: Haiyan Hao, Beijing (CN); Lei Dai, Beijing (CN); Lifei Cai, Beijing (CN)

(21) Appl. No.: 14/778,064

(22) PCT Filed: Feb. 27, 2014
(86) PCT No.: PCT/CN2014/072623

§ 371 Date: Sep. 17, 2015

(30) Foreign Application Priority Data
Mar. 20, 2013 (CN) 201310089765.2

(51) Int. Cl. C09D 11/52; C09D 11/102; H01L 51/00; H01L 51/52; H01B 1/24; C09D 11/38; C09D 11/033

(52) U.S. Cl. CPC C09D 11/52; C09D 11/38; C09D 11/102; C09D 11/033; H01L 51/5206; H01L 51/5234; H01B 1/24; H01L 51/0049; H01L 51/0037; H01L 51/0035; H01L 51/004

(57) ABSTRACT

A transparent carbon nano-tube (CNT) polymer compound conductive inks and preparation methods thereof. The conductive ink includes modified CNT, conductive polymer, water-soluble polymer cosolvent, polymer modification additive, surfactant and deionized water. Preparation is performed to realize uniform dispersion of CNT and conductive polymer solution and the obtained ink has good stability and re-dispersibility. The CNT polymer compound conductive ink and methods can be used for preparing fine electrode patterns under room temperature by adopting such devices as spin coating and ink jet printing. Photoresist conductive ink can be prepared to realize one-off preparation of electrode patterns with fine structures. The ink can be applied for very transparent electrode materials in such devices as flexible OLED displays, solar cells, liquid crystal displays and panels of touch screens. It has such advantages as good compatibility with transparent polymer matrix and strong adhesion to ensure use life of the flexible electrode.

### TECHNICAL FIELD

The present invention relates to the technical field of organic electroluminescence devices, in particular to a transparent carbon nano-tube (CNT) polymer compound conductive ink for transparent electrodes and the preparation method thereof.

### BACKGROUND ART

In such display devices and photovoltaic devices as liquid crystal panel, OLED panel, touch screen, electronic paper and solar cell, transparent electrodes are indispensable components. Indium tin oxide (ITO) forms ITO films on glass substrate, exhibiting excellent transparence and conductivity, so it possesses leading position in application fields of commercial transparent electrodes. With development of science and technology and diversification of application fields of transparent electrodes, however, transparent electrodes must meet requirements such as low square resistance, good transmittance within visible light, flexibility and simple operation technology capable of realizing large area fine coating and filming, which makes that problems which can not be overcome technologically exist in expanded application of ITO films. Indium (In) is a rare element with low reserves in the world and content of In₂O₃ in films is high, so the production cost is high; ITO films are brittle and are easy to generate cracks after many times of periodic bending or compression, causing invalidity of conductivity. When ITO films deposit on matching plastic substrates at low temperature, the film layer exhibits relatively high surface resistance and degree of roughness. Therefore, it is a technical difficulty which must be solved in electronic display fields and application fields of photovoltaic to develop novel flexible transparent electrode materials for replacement of ITO electrodes.

CNT is a kind of carbon materials with typical lamellar hollow structures and body of the CNT consists of hexagonal graphite carbon ring structure units. It is a one-dimensional quantum material with special structures (the radial dimension is in nanometer scale and axial dimension is in micrometer scale). Tube wall consists of several or dozens of layers of coaxial circular pipes. Fixed distance is kept between different layers and it is about 0.34 nm, with diameter at 2˜20 nm. P electrons of carbon atoms on CNT form large range delocalized π-bond. Due to obvious conjugative effect, CNT has some special electrical properties. Because structure of CNT is identical to the lamellar structure of graphite, CNT has very good electrical properties. Due to high electron transfer rate, low resistivity and high transparency, CNT materials have been considered by the field of scientific research and industry to replace ITO transparent electrodes.

Combination of CNT and conducting materials into a compound layer can improve conducting properties of transparent electrodes. In present methods, CNT together with conducting materials is generally manufactured into a mixing solution and then spin coating is carried out or the mixing solution is printed on an electrode. Due to specificity of structure of CNT and bad compatibility with other substances, however, dispersion of CNT in the mixing solution is bad and the mixing solution is unstable and easy to deposit.

### SUMMARY OF THE PRESENT INVENTION

The present invention provides a novel transparent CNT polymer conductive ink is disclosed. In preparation of the ink, modified CNT and conductive polymer are used as raw materials and special cosolvent is adopted. Moreover, the blend technology of solution is adopted to realize uniform dispersion of CNT and conductive polymer solution and the obtained ink has good stability and re-dispersibility.

The present invention also provides preparation method of the transparent CNT polymer conductive ink.

A transparent CNT polymer conductive ink, comprising the following components in the following weight parts:

| | | |
|---|---|---|
| 1. | modified CNT | 0.01%-1%, |
| 2. | conductive polymer | 0.17%-2%, |
| 3. | water-soluble polymer cosolvent | 0.43%-5%, |
| 4. | surfactant | 0.01%-0.05%, |
| 5. | polymer modification additives | 0.037%-0.44%, |
| 6. | deionized water | added to 100%, |

The said modified CNT is prepared by the following method: add 30% HNO₃ aqueous solution into CNT, after dispersion by ultrasonic wave for 40 min, stir at 50-70° C. for 30 min, filter with a 200 μm porous membrane, rinse to neutrality, and dry at 100° C. to obtain the modified CNT after purification.

The said CNT is single-wall CNT (SWCNT), double-wall CNT (DWCNT) or multi-wall CNT (MWCNT) powders.

The said conductive polymer is selected from polyaniline, poly(3,4-ethylenedioxythiophene), polyacetylene or polypyrrole.

The said corresponding polymer cosolvent is selected from polystyrene sulfonate, camphorsulfonic acid, dodecyl benzene sulfonic acid, hexadecyl benzene sulfonic acid or naphthalene sulfonic acid.

The said polymer modification additive is one or more selected from propylene glycol, glycerin, ethylene glycol monobutyl ether, sorbitol, dimethyl sulfoxide and N,N-dimethyl formamide.

The said surfactant is sodium dodecyl benzene sulfonate or polyvinylpyrrolidone.

The said conductive polymer is poly(3,4-ethylenedioxythiophene), the said conductive polymer cosolvent is sodium polystyrene sulfonate, and the said surfactant is polyvinylpyrrolidone

The preparation method of the transparent CNT polymer conductive ink, comprises the following steps:
1) purification and modification of CNT: add 30% HNO₃ aqueous solution into CNT, after dispersion by ultrasonic wave for 40 min, stir at 50-70° C. for 30 min, filter with a 200 μm porous membrane, rinse to neutrality, and dry at 100° C. to obtain the modified CNT after purification;
2) mix and dissolve certain amount of modified CNT after purification and surfactants in certain amount of water, disperse sufficiently by adopting ultrasonic disperser and mechanical stirring, and filter the dispersion solution by a 200 μm porous membrane for many times. The obtained filtrate is dispersion solution of CNT;
3) polymeric modification of conductive polymer: conductive polymer cosolvent: add certain amount of polymer modification additives into the conductive polymer: conductive polymer cosolvent, form clear solution through ultrasonic dispersion and mechanical stirring, filter the solution by a 200 μm porous membrane for many times;
4) blend the solutions obtained in step 2 and step 3 together and form stable and uniform transparent CNT polymer conductive ink through the method of ultrasonic and mechanical stirring.

The said conductive polymer: conductive polymer cosolvent is poly(3,4-ethylenedioxythiophene) (PEDOT): Sodium polystyrene sulfonate (PSS).

In formation of the present invention, except for basic modified CNT, conductive polymer and deionized water, conductive polymer cosolvent and polymer modification additive and surfactant are also added, so that dispersibility of CNT is improved obviously and stability and re-dispersibility of the obtained ink are good.

CNT being conducting transmission materials of conducting film, its dispersion in conductive polymer system is very important. However, surface tension of CNT is large and CNT is easy to agglomerate into particles. Therefore, uniform dispersion of CNT in the ink system is very important. In the present invention, amorphous carbon on surfaces of CNT is removed by adopting the method of acidifying. At the same time, such functional groups as OH and COOH are grafted on surfaces of CNT, reducing agglomeration and CNT and increasing solubility of CNT in water. In addition, stable dispersion of CNT in the ink system can be improved under adjustment effects of surfactants on surface tension of CNT.

The conductive polymer itself is difficult to be soluble in water and it can form a water-soluble solution system under bonding action of polymer cosolvent. In order to adjust its conducting characteristics, some substances with high melting point can be added to improve the conducting properties and these substances are called as conducting additives.

The present invention provides a novel transparent CNT polymer conductive ink is disclosed. In preparation of the ink, modified CNT and conductive polymer are used as raw materials and special cosolvent is adopted. Moreover, the blend technology of solution is adopted to realize uniform dispersion of CNT and conductive polymer solution and the obtained ink has good stability and re-dispersibility. The transparent CNT polymer conductive ink can be used for preparing fine electrode patterns under room temperature by adopting such devices as spin coating and ink jet printing. It can realize preparation of fine electrode patterns through photo-resisting technology and can also be prepared into photoresist type conductive ink to realize one-off preparation of electrode patterns with fine structures.

The transparent CNT ink can be applied for very transparent electrode materials in such devices as flexible OLED display, solar cell, liquid crystal display and panel of touch screen. It has such advantages as good compatibility with transparent polymer matrix and strong adhesion to ensure use life of the flexible electrode.

### BRIEF DESCRIPTION OF THE DRAWINGS

FIG. 1 is Surface morphology images of carbon nano-tube (CNT) and CNT/PEDOT: PSS (Embodiment 1) films.

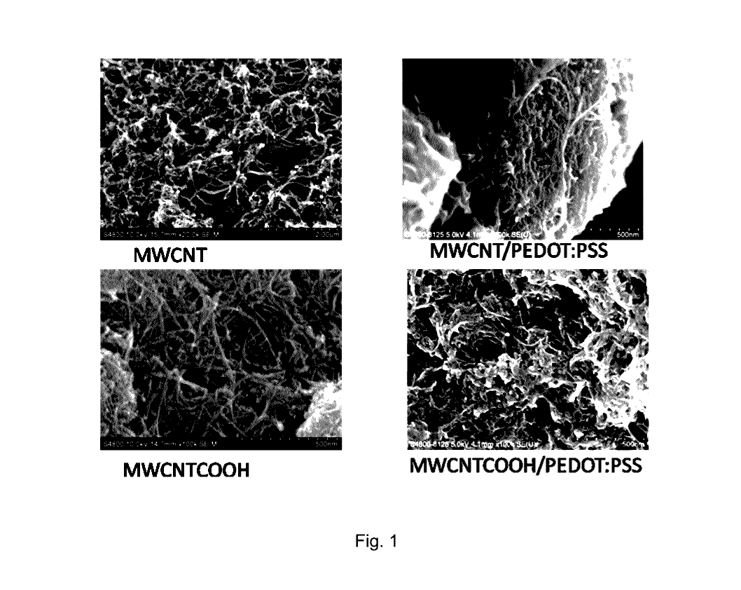

FIG. 2 is the test result of optical transmittance of films prepared in the Embodiment 1.

### DETAILED DESCRIPTION OF THE PREFERRED EMBODIMENTS

The present invention will be further described in details hereinafter with reference to specific embodiments.

### Embodiment 1

| | |
|---|---|
| Modified CNT | 0.05% |
| Poly(3,4-ethylenedioxythiophene) (PEDOT) | 1% |
| Sodium polystyrene sulfonate (PSS) | 1% |
| PVP | 0.03% |
| Glycerin | 0.08% |
| Dimethyl sulfoxide | 0.08% |
| Ethylene glycol monobutyl ether | 0.03% |
| Water | 97.8% |

Preparation Method:

Technological Processes:
1) purification and modification of CNT: add 30% HNO₃ aqueous solution into CNT, after dispersion by ultrasonic wave for 40 min, stir at 50-70° C. for 30 min, filter with a 200 μm porous membrane, rinse to neutrality, and dry at 100° C. to obtain the modified CNT after purification;
2) mix and dissolve certain amount of modified CNT after purification and surfactant PVP in certain amount of water, disperse sufficiently by adopting ultrasonic disperser and mechanical stirring, and filter the dispersion solution by a 200 μm porous membrane for many times. The obtained filtrate is dispersion solution of CNT;
3) polymeric modification of PEDOT: PSS: add certain amount of polymer modification additives into the PEDOT: PSS solution, form clear blue solution through ultrasonic dispersion and mechanical stirring, filter the solution by a 200 μm porous membrane for many times;
4) blend the solutions obtained in step 2 and step 3 together and form stable and uniform transparent CNT polymer compound conductive ink through the method of ultrasonic and mechanical stirring.

### Embodiment 2

| | |
|---|---|
| Modified CNT | 0.05% |
| Poly(3,4-ethylenedioxythiophene) (PEDOT) | 0.8% |
| Sodium polystyrene sulfonate (PSS) | 1% |
| PVP | 0.05% |
| Sorbitol | 0.12% |
| Dimethyl sulfoxide | 0.08% |
| Ethylene glycol monobutyl ether | 0.025% |
| Water | 97% |

The preparation method is the same as that in Embodiment 1.

The transparent CNT polymer conductive ink can be used for preparing fine electrode patterns under room temperature by adopting such devices as spin coating and ink jet printing. It can realize preparation of fine electrode patterns through photo-resisting technology and can also be prepared into photoresist type conductive ink to realize one-off preparation of electrode patterns with fine structures.

Example: the conductive ink in Embodiment 1 is coated on electronic glass substrate by spin coating. Implementation technology: rotation speed 3000 rpm, time 30 s, drying temperature 120° C., and drying time 20 min.

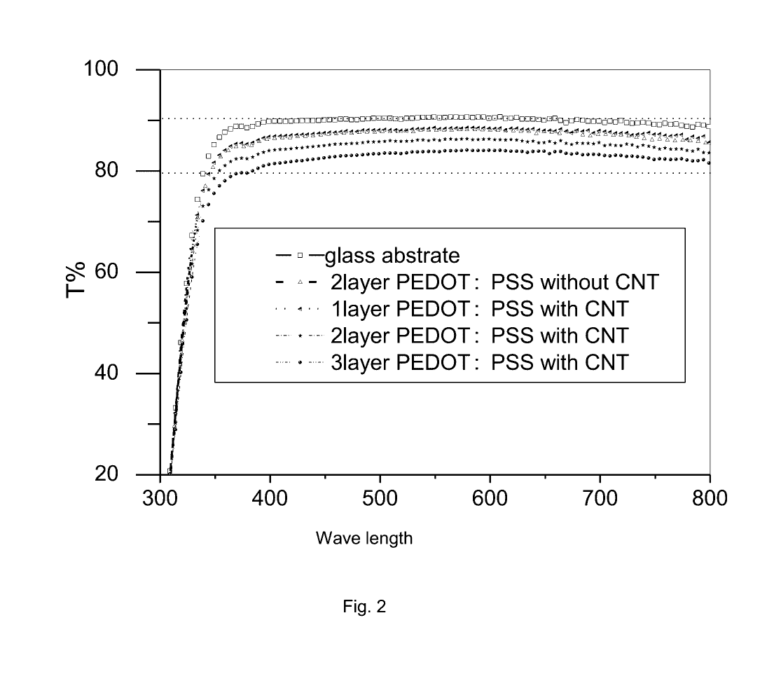

Single layer thickness of the obtained film is 19-23 nm and thickness of three layers of film is 55-60 nm. Within the wave length range of 300-600 nm, the optical transmittance (with respect to the substrate) is larger than 90% and the square resistance of three layers of films reaches up to 150-200Ω/□, as shown in Table 1 and FIG. 2.

TABLE 1
Test results of conductivity and film thickness of films prepared in
Embodiment 1

| | | |
|---|---|---|
| IJ1005-MWNTCOOH-1layer | 1132.5 Ω/□ | 19.7 nm |
| IJ1005-MWNTCOOH-2layers | 317.1 Ω/□ | 40.3 nm |
| IJ1005-MWNTCOOH-3layers | 181.2 Ω/□ | 52.7 nm |

1. A transparent carbon nano-tube (CNT) polymer conductive ink, comprising the following components in the following weight parts:

| | | |
|---|---|---|
| [1.] | modified CNT | 0.01%-1%, |
| [2.] | conductive polymer | 0.17%-2%, |
| [3.] | water-soluble polymer cosolvent | 0.43%-5%, |
| [4.] | surfactant | 0.01%-0.05%, |
| [5.] | polymer modification additives | 0.037%-0.44%, |
| [6.] | deionized water | added to 100%, |

wherein the modified CNT has been prepared b a method that includes:
adding 30% HNO₃ aqueous solution into CNT,
after dispersion by ultrasonic wave for 40 min, stirring at 50-70° C. for 30 min,
filtering with a 200 μm porous membrane,
rinsing to neutrality, and
drying at 100° C. to obtain the modified CNT after purification.

2. The transparent CNT polymer conductive ink according to claim 1, wherein the said CNT is single-wall CNT (SWCNT), double-wall CNT (DWCNT) or multi-wall CNT (MWCNT) powders.

3. The transparent CNT polymer conductive ink according to claim 1, wherein:
the conductive polymer is selected from a group that consists of:
polyaniline,
poly(3,4-ethylenedioxythiophene),
polyacetylene, and
polypyrrole, and
the corresponding polymer cosolvent is selected from a group that consists of:
polystyrene sulfonate,
camphorsulfonic acid,
dodecyl benzene sulfonic acid,
hexadecyl benzene sulfonic acid, and
naphthalene sulfonic acid.

4. The transparent CNT polymer conductive ink according to claim 3, wherein the surfactant is sodium dodecyl benzene sulfonate or polyvinylpyrrolidone.

5. The transparent CNT polymer conductive ink according to claim 4, wherein:
the conductive polymer includes [is] poly(3,4-ethylenedioxythiophene),
the conductive polymer cosolvent includes sodium polystyrene sulfonate, and
the surfactant includes [is] polyvinylpyrrolidone.

6. The transparent CNT polymer conductive ink according to claim 1, wherein the modification additive includes one or more selected from the group that consists of:
propylene glycol,
glycerin,
ethylene glycol monobutyl ether,
sorbitol,
dimethyl sulfoxide and
N,N-dimethyl formamide.

7. The transparent CNT polymer conductive ink according to claim 1, wherein:
the conductive polymer includes poly(3,4-ethylenedioxythiophene),
the conductive polymer cosolvent includes sodium polystyrene sulfonate, and
the surfactant includes polyvinylpyrrolidone.

8. The transparent CNT polymer conductive ink according to claim 1, wherein the transparent CNT polymer conductive ink has been further prepared by a method that includes:
a. purification and modification of CNT including said method that includes:
adding 30% HNO₃ aqueous solution into CNT,
after dispersion by ultrasonic wave for 40 min, stir at 50-70° C. for 30 min, filtering with a 200 μm porous membrane,
rinsing to neutrality, and
drying at 100° C. to obtain the modified CNT after purification;
b. performing an operation that includes:
mixing and dissolving an amount of the modified CNT after purification and surfactants in an amount of water,
dispersing sufficiently by adopting ultrasonic disperser and mechanical stirring, and
filtering the dispersion solution by a 200 μm porous membrane repeatedly, thereby obtaining a dispersion solution of CNT;
c. performing polymeric modification of the conductive polymer, including:
adding an amount of polymer modification additives into the conductive polymer,
forming a clear solution using ultrasonic dispersion and mechanical stirring, and
filtering the solution by a 200 μm porous membrane for many times; and
d. blending the solutions obtained in acts (b.) and (c) together and forming a stable and uniform transparent CNT polymer conductive ink using ultrasonic and mechanical stirring.

9. The method according to claim 8, wherein the said conductive polymer comprises poly(3,4-ethylenedioxythiophene.

10. The transparent CNT polymer conductive ink according to claim 8, wherein the said CNT is single-wall CNT (SWCNT), double-wall CNT (DWCNT) or multi-wall CNT (MWCNT) powders.

11. The transparent CNT polymer conductive ink according to claim 8, wherein:
the conductive polymer is selected from a group that consists of:
polyaniline,
poly(3,4-ethylenedioxythiophene),
polyacetylene, and
polypyrrole, and
the corresponding polymer cosolvent is selected from a group that consists of:
polystyrene sulfonate,
camphorsulfonic acid,
dodecyl benzene sulfonic acid,
hexadecyl benzene sulfonic acid, and
naphthalene sulfonic acid.

12. The transparent CNT polymer conductive ink according to claim 11, wherein the surfactant is sodium dodecyl benzene sulfonate or polyvinylpyrrolidone.

13. The transparent CNT polymer conductive ink according to claim 12, wherein:
the conductive polymer includes poly(3,4-ethylenedioxythiophene),
the conductive polymer cosolvent includes sodium polystyrene sulfonate, and
the surfactant includes polyvinylpyrrolidone.

14. The transparent CNT polymer conductive ink according to claim 8, wherein the polymer modification additive includes one or more selected from the group that consists of:
propylene glycol,
glycerin,
ethylene glycol monobutyl ether,
sorbitol,
dimethyl sulfoxide and
N,N-dimethyl formamide.

15. The transparent CNT polymer conductive ink according to claim 8, wherein:
the conductive polymer includes poly(3,4-ethylenedioxythiophene),
the conductive polymer cosolvent includes sodium polystyrene sulfonate, and
